(19) United States
(12) Patent Application Publication
(10) Pub. No.: US 2012/0094505 A1
(43) Pub. Date: Apr. 19, 2012

(54) METHOD FOR SELECTIVE OXIDATION, DEVICE FOR SELECTIVE OXIDATION, AND COMPUTER-READABLE MEMORY MEDIUM

(75) Inventors: Hideo Nakamura, Yamanashi (JP); Yoshiro Kabe, Yamanashi (JP); Kazuhiro Isa, Yamanashi (JP); Junichi Kitagawa, Yamanashi (JP)

(73) Assignee: TOKYO ELECTRON LIMITED, Tokyo (JP)

(21) Appl. No.: 13/376,678

(22) PCT Filed: Jul. 26, 2010
(86) PCT No.: PCT/JP2010/062518

§ 371 Date: Dec. 7, 2011

(30) Foreign Application Priority Data
Jul. 27, 2009 (JP) 2009-173810

(51) Int. Cl. H01L 21/316; B05C 11/00; C23C 16/50

(52) U.S. Cl. 438/771; 118/723 R; 118/697; 257/E21.282

(57) ABSTRACT

A selective oxidation treatment method in which plasma of a hydrogen gas and an oxygen containing gas is allowed to act on an object to be treated, and in which silicon and a metallic material are exposed in the surface, within a treatment container of a plasma treatment apparatus comprises: after the supply of the hydrogen gas from a hydrogen gas supply source is initiated by using a first inert gas, which passes through a first supply path, as a carrier gas, initiating the supply of the oxygen containing gas from an oxygen containing gas supply source by using a second inert gas, which passes through a second supply path, as a carrier gas before the plasma is ignited; igniting the plasma of a treatment gas including the oxygen containing gas and the hydrogen gas within the treatment container; and selectively oxidizing the silicon by the plasma.

### CROSS-REFERENCE TO RELATED APPLICATIONS

This application is a 35 U.S.C. §371 national stage filling of International Application No. PCT/JP2010/062518, filed Jul. 26, 2010, the entire contents of which are incorporated by reference herein, which claims priority to Japanese Patent Application No. 2009-173810, filed on Jul. 27, 2009, the entire contents of which are incorporated by reference herein.

### TECHNICAL FIELD

The present disclosure relates to a method for selective oxidation, a device for selective oxidation, and a computer-readable memory medium.

### BACKGROUND

In a process for fabricating a semiconductor device, a process of selectively oxidizing only silicon is performed on an object to be treated in which a metallic material and silicon are exposed. For example, a flash memory having a laminated structure called metal-oxide-nitride-oxide-silicon (MONOS) type is known, and in a process for fabricating this type flash memory, a laminated film is formed on a semiconductor wafer (hereinafter, referred to as a ‘wafer’) through chemical vapor deposition (CVD) and then etched with a certain pattern to form a laminated body having a MONOS structure. In order to repair etching damage generated on the surface of silicon exposed during etching, the silicon surface is selectively oxidized by using oxygen-containing plasma. During this selective oxidization treatment, the silicon which has been damaged by etching must be selectively oxidized without oxidizing the metallic material to its maximum level.

In the selective oxidation treatment, a reductive hydrogen gas is used, together with an oxygen gas, as a processing gas, and plasma oxidation is performed in consideration of a mixture ratio of the oxygen gas and the hydrogen gas.

Also, although not related to selective oxidation treatment, a technique of uniformly hardening a Low-k film by controlling a timing of plasma ignition in plasma-modifying the Low-k film and hardening the same has been proposed.

In a related art, in a gas supply sequence for selective oxidation treatment, oxygen gas and hydrogen gas were introduced into a container before plasma was ignited (while a wafer is being pre-heated). However, a problem arises in that a metallic material exposed from the surface of the wafer is oxidized by the influence of the oxygen gas during pre-heating. In order to prevent the metallic material from being oxidized during pre-heating, it may be possible to delay the timing of oxygen introduction, for example, until after the plasma ignition, but in that case, the following problem arises.

In the selective oxidization process, in order to seek the balance between oxidation and reduction, a hydrogen flow rate is set to be greater by a few times than an oxygen flow rate. Also, in order to avoid the risk of explosion, an oxygen gas and a hydrogen gas are supplied to the interior or proximity of a treatment container through respective separate paths. In general, an oxygen gas is supplied to the treatment container by a single gas line, and the hydrogen gas is supplied, along with an inert gas such as argon (Ar), or the like, to the interior of the treatment container. For example, although supplying of the oxygen gas and the hydrogen gas starts simultaneously, since time is taken for the oxygen gas of a small flow rate to be introduced into the treatment container through a pipe, formation of oxygen plasma is considerably delayed to minimize the amount of oxidation. Also, after plasma ignition, plasma of inert gas and hydrogen gas is generated at the initial stage following the plasma ignition, strengthening sputtering to roughen the surface of silicon.

In order to speed up the formation of oxygen plasma, it may be possible to change an introduction path of a carrier gas to introduce oxygen gas at a smaller flow rate along with the carrier gas such as Ar, or the like. However, when hydrogen gas is solely introduced, conversely, an introduction timing of the hydrogen gas is delayed to cause the metallic material on the wafer to be exposed to the oxygen plasma at the initial stage following plasma ignition, resulting in oxidization of the metallic material.

As discussed above, in the selective oxidation treatment, the balance between oxidation and reduction within the treatment container is readily lost due to the supply timing of the oxygen gas and the hydrogen gas. Therefore, when the oxidation atmosphere becomes stronger, the metallic material is oxidized, and conversely, when the reduction atmosphere becomes stronger, there is a concern that the surface of the silicon becomes rough due to sputtering. Also, when the timing of the supply of oxygen gas is delayed, generation of oxygen plasma is delayed to lead to a failure of obtaining a sufficient oxidation quotient, thus degrading throughput.

### SUMMARY

According to one embodiment of the present disclosure, there is provided a selective oxidation treatment method in which plasma of a hydrogen gas and an oxygen containing gas is allowed to act on an object to be treated, in which silicon and a metallic material are exposed in the surface, within a treatment container of a plasma treatment apparatus so as to selectively oxidize the silicon by the plasma. The method comprises: after the supply of the hydrogen gas from a hydrogen gas supply source is initiated by using a first inert gas, which passes through a first supply path, as a carrier gas, initiating the supply of the oxygen containing gas from an oxygen containing gas supply source by using a second inert gas, which passes through a second supply path different from the first supply path, as a carrier gas before the plasma is ignited; igniting the plasma of a treatment gas including the oxygen containing gas and the hydrogen gas within the treatment container; and selectively oxidizing the silicon by the plasma.

According to one embodiment of a selective oxidation treatment apparatus of the present disclosure, the apparatus comprises: a treatment container configured to accommodate an object to be treated; a loading table configured to load the object to be treated within the treatment container; a gas supply device configured to supply a treatment gas to the interior of the treatment container; an exhaust device configured to decompress and exhaust the interior of the treatment container; a plasma generation unit configured to introduce an electromagnetic wave into the treatment container to generate plasma of the treatment gas; and a controller configured to provide control to allow the plasma generated within the treatment container to act on the object to be treated, in which silicon and a metallic material are exposed in the surface, in order to selectively oxidize the silicon, wherein the gas supply device includes a first inert gas supply source, a second inert gas supply source, a hydrogen gas supply source, and an oxygen containing gas supply source, and has inert gas supply paths of two lines including a first supply path for supplying a first inert gas from the first inert gas supply source to the treatment container and a second supply path for supplying a second inert gas from the second inert gas supply source to the treatment container.

According to the present disclosure, there is provided a computer-readable memory medium having a control program operating on a computer stored thereon. The control program, when executed, causes the computer to provide control to perform a selective oxidation treatment method in which plasma of a hydrogen gas and an oxygen containing gas is allowed to act on an object to be treated, in which silicon and a metallic material are exposed in the surface, within a treatment container of a plasma treatment apparatus so as to selectively oxidize the silicon. The computer readable memory includes instructions to perform the selective oxidation treatment method, the instructions comprises: after the supply of the hydrogen gas from a hydrogen gas supply source is initiated by using a first inert gas, which passes through a first supply path, as a carrier gas, initiating the supply of the oxygen containing gas from an oxygen containing gas supply source by using a second inert gas, which passes through a second supply path different from the first supply path, as a carrier gas before the plasma is ignited; igniting the plasma of a treatment gas including the oxygen containing gas and the hydrogen gas within the treatment container; and selectively oxidizing the silicon by the plasma.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic sectional view showing an example of a selective oxidation treatment apparatus suitable for implementing a method according to the present disclosure.

FIG. 2 is a view showing the structure of a planar antenna.

FIG. 3 is an explanatory view showing an example of the configuration of a controller.

FIG. 4 is a sectional view of an object to be treated having a MONOS structure before a selective oxidation treatment.

FIG. 5 is a sectional view of an object to be treated having a MONOS structure after the selective oxidation treatment.

FIG. 6 is a view showing an example of a timing chart of a selective oxidation treatment based on a gas supply sequence according to the present disclosure.

FIG. 7 is an explanatory view showing an example of the configuration of gas lines.

FIG. 8 is an explanatory view showing another example of the configuration of the gas lines.

FIG. 9 is a view showing a change in the flow rates of H₂ gas and O₂ gas within a treatment container.

FIG. 10 is a view showing a timing chart of a selective oxidation treatment based on a gas supply sequence according to a comparative example.

FIG. 11 is a view showing a timing chart of a selective oxidation treatment based on a gas supply sequence according to another comparative example.

FIG. 12 is a view showing a timing chart of a selective oxidation treatment based on a gas supply sequence according to yet another comparative example.

FIG. 13 is a view showing a timing chart of a selective oxidation treatment based on a gas supply sequence according to still another comparative example.

FIG. 14 is a graph showing the composition of a treatment gas and the relationship between oxidation and reduction peaks of metallic materials.

FIG. 15 is a graph showing timing of plasma ignition and the relationship between oxidation and reduction peaks of a tungsten material.

FIG. 16 is a graph showing timing of plasma ignition and the relationship between oxidation and reduction peaks of a titanium material.

FIG. 17 is a flowchart illustrating an example of the process of determining reliability of the selective oxidation treatment.

### DETAILED DESCRIPTION

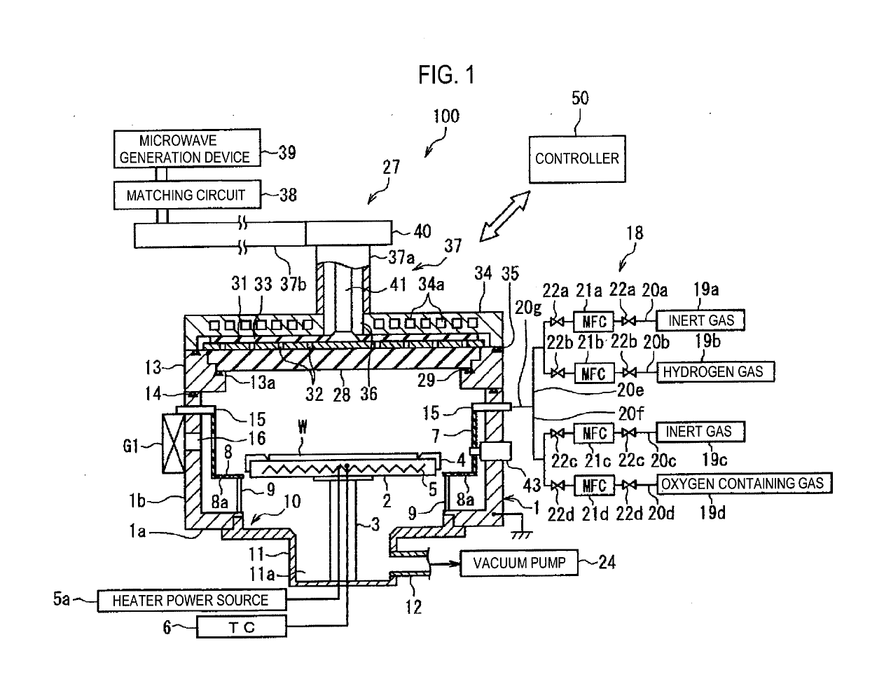

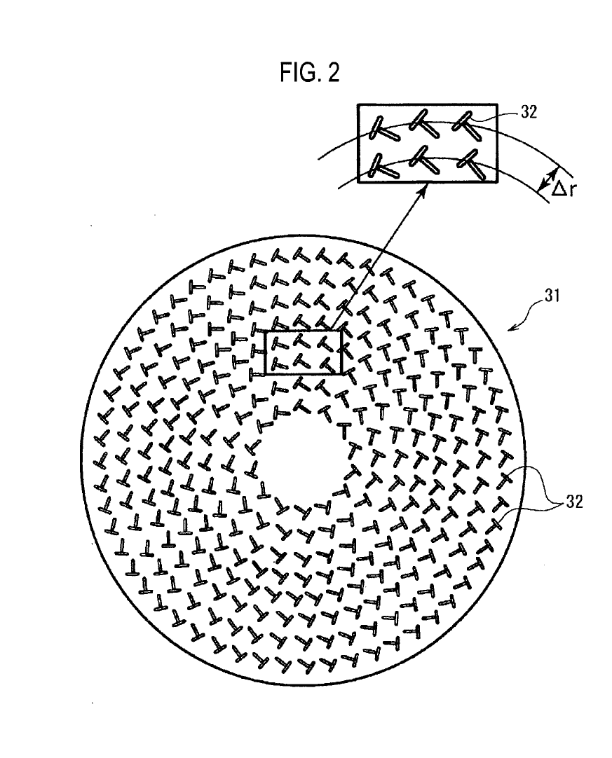

Embodiments of the present disclosure will now be described in detail with reference to the accompanying drawings. First, FIG. 1 is a sectional view schematically showing the configuration of a plasma treatment apparatus 100 which can be used for a selective oxidation treatment method according to the present disclosure. Also, FIG. 2 is a plan view showing a planar antenna of the plasma treatment apparatus 100 of FIG. 1.

The plasma treatment apparatus 100 is configured as a radial line slot antenna (RLSA) microwave plasma treatment apparatus capable of generating microwave excitation plasma of high density and low electron temperature by introducing microwaves into a treatment container by a planar antenna having holes with the shape of a plurality of slots, in particular, RLSA. The plasma treatment apparatus 100 is able to process at a plasma density of 1×10¹⁰ to 5×10¹²/cm² and also by plasma having low electron temperature of 0.7 to 2 eV. The plasma treatment apparatus 100 can be appropriately used as a selective oxidation treatment apparatus for forming silicon oxide (SiO₂) film by selectively oxidizing silicon, without oxidizing a metallic material on an object to be treated to its maximum level in a process of fabricating various semiconductor devices.

The plasma treatment apparatus 100 includes a treatment container 1 configured to be air-tight, a gas supply device 18 for supplying gas into the treatment container 1, an exhaust device having a vacuum pump 24 for decompressing and exhausting the interior of the treatment container 1, a microwave introduction mechanism 27 as a plasma generation unit for generating plasma in the treatment container 1, and a controller 50 for controlling each of the elements of the plasma treatment apparatus 100, as major elements.

The treatment container 1 is formed by a container having a substantially cylindrical shape which is grounded. Also, the treatment container 1 may be formed by a container having an angular container shape. The treatment container 1 has a lower wall 1a and a side wall 1b made of a metal such as aluminum or the like, or an alloy thereof.

A loading table 2 is installed within the treatment container 1 in order to horizontally support wafer W, which is an object to be treated. The loading table 2 is made of a material having high heat conductivity, e.g., ceramics such as AlN, or the like. The loading table 2 is supported by a cylindrical support member 3 extending upward from the center of a lower portion of an exhaust chamber 11. The support member 3 is made of, for example, ceramics such as AlN, or the like.

Further, a cover ring 4 is installed on the loading table 2 in order to cover an outer edge portion and guiding the wafer W. The cover ring 4 is an annular member or an entire surface cover made of a material such as quartz, SiN, or the like. Accordingly, the loading table can be prevented from being sputtered by plasma to generate metal such as Al, or the like.

Also, a resistance heating type heater 5 is buried as a temperature regulation mechanism in the loading table 2. The heater 5 is power-fed from a heater power source 5a to heat the loading table 2 to thus uniformly heat the wafer W, which is a substrate to be processed.

Additionally, a thermocouple (TC) 6 is disposed in the loading table 2. A heating temperature of the wafer W can be controlled within the range from, for example, room temperature to 900 degrees C. by measuring the temperature of the loading table 2 by means of the thermocouple 6.

Also, a wafer support pin (not shown) is installed on the loading table 2 to supportedly lift or lower the wafer W. Each wafer support pin may be installed to be protruded or depressed with respect to the surface of the loading table 2.

A cylindrical liner 7 made of quartz is installed at an inner circumference of the treatment container 1. Also, a baffle plate 8 made of quartz and having a plurality of exhaust holes 8a is annularly installed at an outer circumference of the loading table 2 in order to uniformly exhaust the interior of the treatment container 1. The baffle plate 8 is supported by a plurality of support columns 9.

A circular opening 10 is formed at a substantially central portion of the lower wall la of the treatment container 1. An exhaust chamber 11 is installed on the lower wall 1a such that it communicates with the opening 10 and protrudes downward. The exhaust chamber 11 is connected to an exhaust pipe 12 and is connected to a vacuum pump 24 through the exhaust pipe 12.

A plate 13 having the center opened in a circular shape is jointed to an upper portion of the treatment container 1. The inner circumference of the opening protrudes toward an inner side (inner space of the treatment container) and forms an annular support 13a. The plate 13 serves as a cover which is disposed at the upper portion of the treatment container 1 and can be opened and closed. The plate 13 and the treatment container 1 are sealed to be air tight by a sealing member 14.

An annular gas introduction unit 15 is installed on the side wall 1b of the treatment container 1. The gas introduction unit 15 is connected to the gas supply device 18 for supplying oxygen containing gas or plasma excitation gas. Also, a plurality of gas lines (pipes) may be connected to the gas introduction unit 15. Also, the gas introduction unit 15 may be installed to have a nozzle shape or a shower type.

An inlet/outlet 16 for carrying in and carrying out the wafer W between the plasma treatment apparatus 100 and a transfer chamber 103 adjacent thereto, and a gate valve G1 for opening and closing the inlet/outlet 16 are installed on the side wall 1b of the treatment container 1.

The gas supply device 18 includes gas supply sources (e.g., a first inert gas supply source 19a, a hydrogen gas supply source 19b, a second inert gas supply source 19c, and an oxygen containing gas supply source 19d), pipes (e.g., gas lines 20a, 20b, 20c, 20d, 20e, 20f, and 20g), a flow rate control device (e.g., mass flow controllers 21a, 21b, 21c, and 21d), and valves (e.g., switching valves 22a, 22b, 22c, and 22d). In addition, the gas supply device 18 may have a purge gas supply source, or the like, used to replace the atmosphere, for example, within the treatment container 1, as an additional gas supply source (not shown).

As the inert gas, for example, a rare gas may be used. The rare gas may include, for example, Ar gas, Kr gas, Xe gas, He gas, or the like. Among them, Ar gas is preferably used in terms of economical efficiency. Also, as the oxygen containing gas, for example, oxygen gas (O₂), steam (H₂O), nitrogen monoxide (NO), dinitrogen monoxide (N₂O), or the like may be used.

The inert gas and hydrogen gas supplied from the first inert gas supply source 19a and the hydrogen gas supply source 19b of the gas supply device 18 join the gas line 20e through the gas lines 20a and 20b, respectively, reach the gas introduction unit 15 through the gas line 20g, and are introduced from the gas introduction unit 15 into the treatment container 1. Also, the inert gas and the oxygen containing gas supplied from the second inert gas supply source 19c and the oxygen containing gas supply source 19d of the gas supply device 18 join the gas line 20f through the gas lines 20c and 20d, respectively, reach the gas introduction unit 15 through the gas line 20g, and are introduced from the gas introduction unit 15 into the treatment container 1. Mass flow controllers 21a, 21b, 21c, and 21d, and a set of switching valves 22a, 22b, 22c, and 22d before and after the mass flow controllers 21a, 21b, 21c, 21d are installed on the respective gas lines 20a, 20b, 20c, 20d connected to the respective gas supply sources. With such a configuration of the gas supply device 18, the supplied gas can be changed or a flow rate of the supplied gas can be controlled.

The exhaust device includes the vacuum pump 24. As the vacuum pump 24, for example, a high speed vacuum pump such as a turbo molecular pump, or the like may be used. As described above, the vacuum pump 24 is connected to the exhaust chamber 11 of the treatment container 1 through the exhaust pipe 12. The gas within the treatment container 1 uniformly flows in a space 11a of the exhaust chamber 11, and is exhausted from the space 11a to the outside through the exhaust pipe 12 by operating the vacuum pump 24. Accordingly, the interior of the treatment container 1 can be decompressed at a high speed to reach a certain degree of vacuum, e.g., up to 0.133 Pa.

Now, the configuration of the microwave introduction mechanism 27 will be described. The microwave introduction mechanism 27 includes a microwave transmission plate 28, the planar antenna 31, a slow-wave member 33, a cover member 34, a waveguide 37, a matching circuit 38, and a microwave generation device 39, as major elements. The microwave introduction mechanism 27 is a plasma generation unit for generating plasma by introducing electromagnetic waves (microwaves) into the treatment container 1.

The microwave transmission plate 28 for allowing microwaves to be transmitted therethrough is supported on a support 13a that protrudes toward an inner circumference of the plate 13. The microwave transmission plate 28 is made of a dielectric, e.g., quartz or ceramic such as Al₂O₃, AlN, or the like. The microwave transmission plate 28 and the support 13a for supporting the microwave transmission plate 28 are sealed to be air tight through the sealing member 29. Thus, the interior of the treatment container 1 is maintained to be air tight.

The planar antenna 31 is installed to face the loading table 2, at an upper side of the microwave transmission plate 28. The planar antenna 31 has a disk-like shape. Also, the shape of the planar antenna 31 is not limited to the disk-like shape but may have, for example, a quadrangular plate shape. The planar antenna 31 is hung on an upper end portion of the plate 13.

The planar antenna 31 is formed of, for example, a copper plate or an aluminum plate with a surface thereof plated with gold or silver. The planar antenna 31 has a plurality of microwave radiation holes 31 having a slot shape to radiate microwaves. The microwave radiation holes 32 are formed to penetrate the planar antenna 31, in a certain pattern.

As shown in FIG. 2, each of the microwave radiation holes 32 has, for example, a thin, long quadrangular shape (slot shape). And, typically, the adjacent microwave radiation holes 32 are disposed in a T-shape. Also, the microwave radiation holes 32 combined in a certain shape (e.g., T-shape) are disposed in an overall shape of concentric circles.

The length and an array interval of the microwave radiation holes 32 is determined depending on the wavelength λg of the microwaves. For example, the interval of the microwave radiation holes 32 is disposed to be λg/4 to λg. In FIG. 2, the interval between the adjacent microwave radiation holes 32 formed in the shape of concentric circles is indicated as Δr. Also, the shape of the microwave radiation holes 32 may have other shapes such as a circular shape, a shape of a circular arc, or the like. Also, the disposition form of the microwave radiation holes 32 is not particularly limited and they may be disposed in, for example, a spiral shape, radially, or the like, in addition to the shape of concentric circles.

The slow-wave member 33 having a permittivity greater than that of a vacuum is installed on an upper surface of the planar antenna 31. Since the wavelength of microwaves is lengthened in the vacuum, the slow-wave member 33 has a function of shortening the wavelength of microwaves to adjust plasma. The slow-wave member 33 may be made of a material such as quartz, a polytetrafluoroethylene resin, a polyimide resin, or the like.

Also, the planar antenna 31 and the microwave transmission plate 28, and the slow-wave member 33 and the planar antenna 31 may be in contact or separated, but preferably, they are in contact.

The cover member 34 is installed at an upper portion of the treatment container 1 in order to cover the planar antenna 31 and the slow-wave member 33. The cover member 34 may be made of a metallic material such as aluminum, stainless steel, or the like. A flat waveguide is formed by the cover member 34 and the planar antenna 31. An upper end portion of the plate 13 and the cover member 34 are sealed by the sealing member 35. Also, a coolant flow path 34a is formed on an upper portion of the cover member 34. The cover member 34, the slow-wave member 33, the planar antenna 31, and the microwave transmission plate 28 may be cooled by allowing a coolant to flow through the coolant flow path 34a. Also, the planar antenna 31 and the cover member 34 are grounded.

An opening 36 is formed at the center of an upper wall (ceiling) of the cover member 34, and a waveguide 37 is connected to the opening 36. The microwave generation device 39 for generating microwaves is connected to the other end portion of the waveguide 37 through the matching circuit 38.

The waveguide 37 includes a coaxial waveguide 37a extending upward from the opening 36 of the cover member 34 and having a circular section, and a rectangular waveguide 37b extending in a horizontal direction and connected to an upper end portion of the coaxial waveguide 37a through a mode converter 40. The mode converter 40 has a function of converting microwaves propagating in a TE mode within the rectangular waveguide 37b into a TEM mode.

An internal conductor 41 extends at the center of the coaxial waveguide 37a. A lower end portion of the internal conductor 41 is fixedly connected to the center of the planar antenna 31. With such a structure, microwaves can propagate radially, effectively, and uniformly to the flat waveguide formed by the cover member 34 and the planar antenna 31 through the internal conductor 41 of the coaxial waveguide 37a.

By the microwave introduction mechanism 27 having the foregoing configuration, microwaves generated by the microwave generation device 39 propagate to the planar antenna 31 through the waveguide 37 and are then introduced into the treatment container 1 through the radiation holes (slots) 32 of the planar antenna 31 and the microwave transmission plate 28. Also, as the frequency of microwaves, for example, 2.45 GHz may be preferably used, or 8.35 GHz, 1.98 GHz, or the like may also be used.

A monochromator 43, which is an emitted light detection device for detecting emitted light of plasma, is installed on the side wall 1b of the treatment container 1 at a height substantially equal to the upper surface of the loading table 2. The monochromator 43 may detect emitted light (wavelength of 777 nm) of O radicals and emitted light (wavelength of 656 nm) of H radicals in plasma.

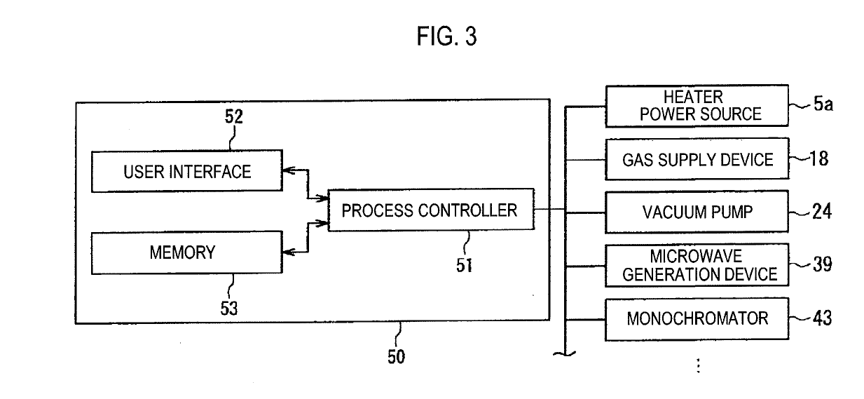

Each of the elements of the plasma treatment apparatus 100 are connected to and controlled by the controller 50. The controller 50 has a computer, and for example, as shown in FIG. 3, the controller 50 includes a process controller 51 having a CPU, and a user interface 52 and a memory 53 connected to the process controller 51. The process controller 51 is a control unit for generally or collectively controlling the respective elements of the plasma treatment apparatus 100, e.g., the heater power source 5a, the gas supply device 18, the vacuum pump 24, the microwave generation device 39 in relation to the process conditions such as temperature, pressure, a gas flow rate, a microwave output, or the like, as well as the monochromator 43, or the like which is a plasma emission measurement unit.

The user interface 52 includes a keyboard for performing a command input manipulation, or the like by a process manager to manage the plasma treatment apparatus 100, a display for visually displaying an operational situation of the plasma treatment apparatus 100, and the like. Further, the memory 53 preserves a recipe having a control program (software) for realizing various treatments executed in the plasma treatment apparatus 100 under the control of the process controller 51, treatment condition data, or the like recorded therein.

In addition, as necessary, a certain recipe is retrieved from the memory 53 according to an instruction, or the like from the user interface 52 and executed in the process controller 51, thereby performing a desired treatment within the treatment container 1 of the plasma treatment apparatus 100 under the control of the process controller 51. Also, a recipe stored in a computer-readable storage medium, e.g., a CD-ROM, a hard disk, a flexible disk, a flash memory, a DVD, a Blu-ray disk, or the like, may be used as the recipe such as the control program, treatment condition data, or the like, or a recipe may be frequently transmitted from a different device, e.g., through a dedicated line, and used online.

In the plasma treatment apparatus 100 configured as described above, plasma treatment can be performed without damaging a basic layer, or the like, at a low temperature of 600 degrees C. or lower. Also, since the plasma treatment apparatus 100 has excellent plasma uniformity, treatment uniformity on the surface of even the large wafer W having a diameter of, e.g., 300 nm or greater, can be realized.

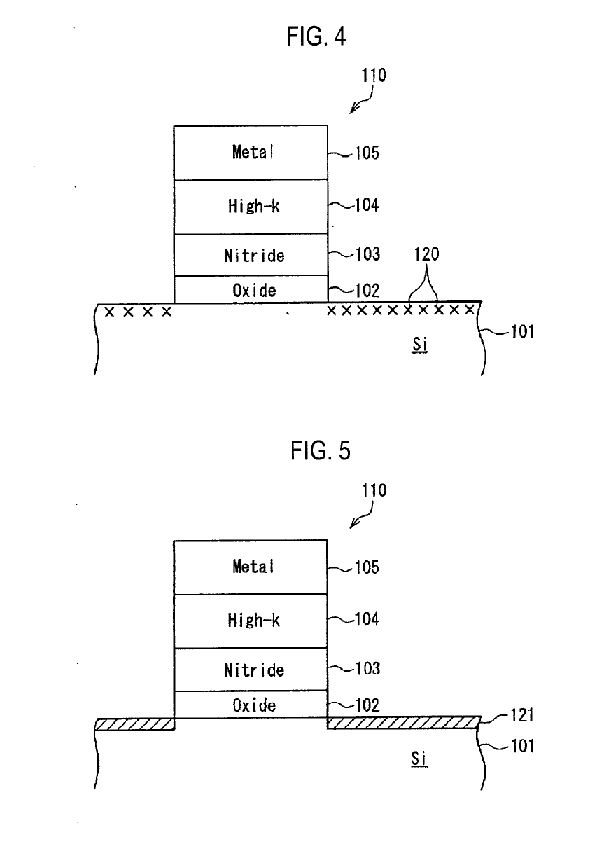

Now, a selective oxidation treatment method performed in the plasma treatment apparatus 100 will be described with reference to FIGS. 4 and 5. First, a treating object of the selective oxidation treatment method according to the present disclosure will be described. A treating object in the present disclosure may be an object to be treated in which silicon and a metallic material are exposed in the surface, and which has, for example, a lamination body 110 having a MONOS structure formed on a silicon layer 101 of wafer W through etching as shown in FIG. 4. The lamination body 110 has a structure in which a silicon oxide film 102, a silicon nitride film 103, a high-permittivity (high-k) film 104 such as alumina (Al₂O₃), or the like, and a metallic material film 105 are sequentially laminated on the silicon layer 101. The metallic material film 105 refers to a film made of a ‘metallic material’, and in the present disclosure, the term ‘metallic material’ is used as a word of a concept including a metallic compound such as silicide, nitride, or the like of metals such as Ti, Ta, W, Ni, or the like, as well as the metals. The metallic material film 105 may include both of a metal and a metallic compound. The lamination body 110 is formed in the process of fabricating, e.g., a MONOS type flash memory device. Etching damage 120 such as multiple defects, or the like is generated on the surface of the silicon layer 101 due to etching for forming the lamination body 110. Selective oxidation aims at recovering the etching damage 120, and to this end, it is required to selectively (predominantly) oxidize only the surface of the silicon layer 101 without oxidizing the exposed metallic material film 105 to its maximum level.

[Order of Selective Oxidation Treatment]

First, the wafer W, a treating object, is transferred into the plasma treatment apparatus 100 by a transfer device (not shown), loaded on the loading table 2, and then heated by the heater 5. Next, while the interior of the treatment container 1 of the plasma treatment apparatus 100 is being decompressed and exhausted, a combination of a rare gas and a hydrogen gas, and a combination of a rare gas and an oxygen containing gas at a certain flow rate are introduced into the treatment container 1 through the gas introduction unit 15 from the first inert gas supply source 19a, the hydrogen gas supply source 19b, the second inert gas supply source 19c, and the oxygen containing gas supply source 19d of the gas supply device 18. In this manner, the interior of the treatment container 1 is adjusted to have a certain pressure. Since the reductive hydrogen gas is included in the treatment gas, balancing of oxidizing power and reducing power is maintained, so only the surface of the silicon layer 101 can be selectively oxidized while restraining the metallic material film 105 from being oxidized. A timing of the treatment gas supply and a timing of plasma ignition in the selective oxidation treatment will be described later.

Next, microwaves of a certain frequency, e.g., 2.45 GHz, generated by the microwave generation device 39 is guided to the waveguide 37 through the matching circuit 38. The microwaves guided to the waveguide 37 sequentially passes through the rectangular waveguide 37b and the coaxial waveguide 37a, and then is supplied to the planar antenna 31 through the internal conductor 41. Namely, the microwaves propagate in the TE mode in the rectangular waveguide 37b, and the microwaves in the TE mode is converted into the TEM mode by the mode converter 40 and propagates to the flat waveguide configured by the cover member 34 and the planar antenna 31 through the coaxial waveguide 37a. The microwaves are also radiated to an upper space of the wafer W in the treatment container 1 through the microwave transmission plate 28 from the microwave radiation holes 32 which are slot shaped and penetrate the planar antenna 31. An output of the microwave at this time may be selected from a range of 1000 W to 4000 W when the wafer W having a diameter of, for example, 200 mm or greater is treated.

An electromagnetic field is formed in the treatment container 1 by the microwaves radiated to the treatment container 1 through the microwave transmission plate 28 from the planar antenna 31, and the inert gas, the hydrogen gas, and the oxygen containing gas become plasma. This excited plasma has a high density of about 1×10¹⁰ to 5×10¹²/cm² and has a low electron temperature of about 1.2 eV or lower in the vicinity of the wafer W. Also, a selective oxidation treatment is performed on the wafer W by an action of active species (ion or radical) of the plasma. Namely, as shown in FIG. 5, the metallic material film 105 is not oxidized and the surface of the silicon layer 101 is selectively oxidized to form a Si—O bond to thereby form the silicon oxide film 121. The etching damage 120 on the surface of the silicon layer 101 is recovered by the formation of the silicon oxide film 121. The selective oxidation treatment conditions are as follows.

[Selective Oxidation Treatment Conditions]

Preferably, a combination of a rare gas and a hydrogen gas and a combination of a rare gas and an oxygen containing gas is used as the treatment gas of the selective oxidation treatment. As the rare gas, Ar gas is preferably used, and as the oxygen containing gas, O₂ gas is preferably used. Here, since the silicon is predominantly oxidized while restraining oxidation of the metallic material by maintaining the balance between oxidizing power and reducing power, preferably, the ratio (percentage of the oxygen containing gas flow/entire treatment gas flow rate) of the volume flow rate of the oxygen containing gas to that of the entire treatment gas in the treatment container 1 ranges from 0.5% to 50%, and more preferably, can also be in ranges from 1% to 25%. Also, for the same reason, preferably, the ratio (percentage of the hydrogen gas flow/entire treatment gas flow rate) of the volume flow rate of the hydrogen gas to that of the entire treatment gas in the treatment container 1 ranges from 0.5% to 50%, and more preferably, can also be in ranges from 1% to 25%.

Further, in order to selectively oxidize the silicon surface, without oxidizing the metallic material to its maximum level depending on the balance between oxidizing power and reducing power, preferably, the ratio (hydrogen gas flow rate: oxygen containing gas flow rate) of the volume flow rates between the hydrogen gas and the oxygen containing gas may be within the range of 1:1 to 10:1, more preferably, can also be 2:1 to 8:1, and most preferably, be 2:1 to 4:1. When the ratio of the volume flow rate of the hydrogen gas to the oxygen containing gas 1 is less than 1, the metallic material is likely to be oxidized, and when the ratio exceeds 10, the silicon is likely to be damaged.

In the selective oxidation treatment, for example, preferably, the flow rate of the inert gas is set to be the ratio of the flow rate within the range of 100 mL/min(sccm) to 5000 mL/min(sccm) as the sum of two lines from the first inert gas supply source 19a and the second inert gas supply source 19c. Preferably, the flow rate of the oxygen containing gas can be set to be the ratio of the flow rate within the range of 0.5 mL/min(sccm) to 100 mL/min(sccm). Preferably, the flow rate of the hydrogen gas can be set to be the ratio of the flow rate within the range of 0.5 mL/min(sccm) to 100 mL/min(sccm).

Also, a treatment pressure may be preferably within the range of 1.3 Pa to 933 Pa in terms of improving selectivity in the selective oxidation treatment, and more preferably within the range of 133 Pa to 667 Pa. When the treatment pressure in the selective oxidation treatment exceeds 933 Pa, the oxidation quotient is likely to degrade, and when the treatment pressure is less than 1.3 Pa, the chamber is likely to be damaged and particle contamination may easily occur.

Further, the power density of the microwave is preferably within the range of 0.51 W/cm² to 2.56 W/cm² in terms of obtaining sufficient oxidation quotient. Also, the power density of the microwave refers to microwave power supplied per 1 cm² of the area of the microwave transmission plate 28 (which is the same, hereinafter).

Also, for example, a heating temperature of the wafer W is set to be preferably within the range of room temperature to 600 degrees C. as the temperature of the loading table 2, more preferably within the range of 100 degrees C. to 600 degrees C., and most preferably within the range of 100 degrees C. to 300 degrees C.

The foregoing conditions are preserved as a recipe in the memory 53 of the controller 50. The process controller 51 reads the recipe and transmits a control signal to the respective elements, e.g., the gas supply device 18, the vacuum pump 24, the microwave generation device 39, the heater power source 5a, or the like of the plasma treatment apparatus 100, whereby the selective oxidation treatment is performed under the desired conditions.

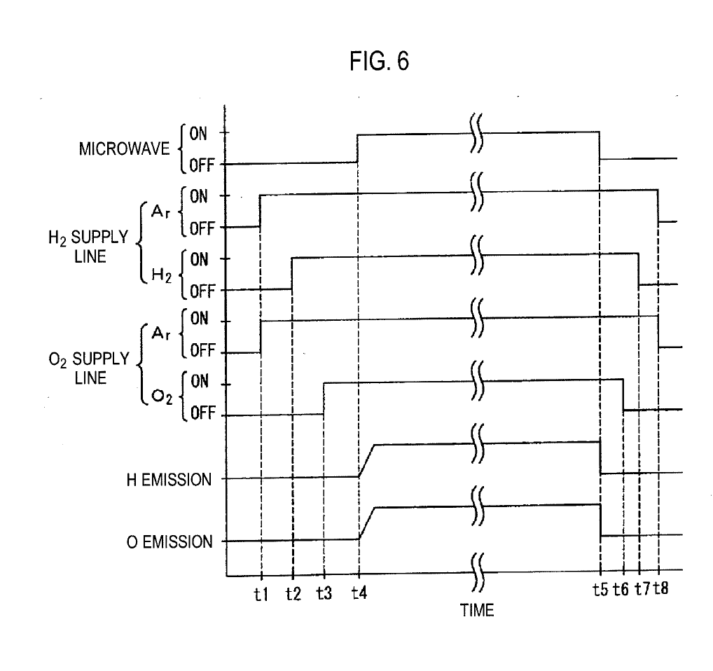

Next, an introduction of a treatment gas in the selective oxidation treatment performed in the plasma treatment apparatus 100 and a timing of plasma ignition will be described with reference to the timing chart of FIG. 6. Here, an Ar gas as an inert gas serving as a plasma generating gas for stably generating plasma and as a carrier gas, and O₂ gas as an oxygen containing gas will be described by way of example. In FIG. 6, a period from a supply initiation t1 of Ar gas to a supply termination t8 is shown.

First, supply of the Ar gas is initiated at t1 from the first inert gas supply source 19a and the second inert gas supply source 19c. The Ar gas is separately introduced into the treatment container 1 through a first supply path including the gas lines 20a, 20e, and 20g from the first inert gas supply source 19a and a second supply path including the gas lines 20c, 20f, and 20g from the second inert gas supply source 19c. The flow rate of Ar gas of the first supply path and that of the second supply path may be set to be, for example, equal.

Next, supply of H₂ gas is initiated at t2. The H₂ gas is supplied through the gas line 20b and the gas lines 20e and 20g from the hydrogen gas supply source 19b, and mixed with the Ar gas from the first inert gas supply source 19a in the gas lines 20e and 20g, so as to be introduced into the treatment container 1.

After the supply of H₂ gas is initiated at t2, supply of O₂ gas is then initiated at t3. The O₂ gas is supplied through the gas lines 20d, 20f, and 20g from the oxygen containing gas supply source 19d, and mixed with the Ar gas from the second inert gas supply source 19c in the gas lines 20f and 20g, so as to be introduced into the treatment container 1.

Thereafter, power of the microwave is turned on at t4 to initiate supply of microwaves to thereby ignite plasma. Plasma using Ar, H₂, and O₂ as a raw material is ignited within the treatment container by the supply of the microwave, initiating a selective oxidation treatment. At the time t4 of the plasma ignition, since H₂ gas and O₂ gas have been already introduced into the treatment container 1, H emission and O emission are observed by the monochromator 43 almost at the same time of the plasma ignition as shown in FIG. 6.

In FIG. 6, t1, t2, and t3 are timing of the initiation of supply of each gas. Thus, until each gas moves to be introduced into the treatment container 1 through the respective gas supply paths formed by the gas lines 20a to 20g after each gas is initiated to be supplied at t1, t2, and t3 by opening the valves 22a to 22d of the gas supply device 18, a time lag is generated depending on the length of the sum of pipes and the diameter of pipes (i.e., the sum volume of the interior of the pipes) in each of the gas supply paths. In particular, in the case of O₂ at a small flow rate, although Ar is provided as a carrier gas, a certain time is required for O₂ to reach the interior of the treatment container 1 after the initiation of supply. In the present embodiment, in consideration of the time lag, the supply of O₂ gas is initiated at the timing of t3 which is ahead of the plasma ignition t4 by a certain time. Accordingly, O₂ gas reaches the interior of the treatment container 1 at the time t4 of the plasma ignition, and preferably, since it can exist at a certain ratio of volume flow rate with H₂ gas, O₂ gas can become rapidly plasma and emission of O radicals is observed.

A time duration from the initiation t3 of supply of O₂ gas to the plasma ignition t4 may be determined depending on the length of the sum of the pipes of the gas lines 20d, 20f, and 20g and the diameter of the pipes (the volume of the interior of the pipes) from the oxygen containing gas supply source 19d to the treatment container 1, and for example, it is preferably within the range of 5 seconds to 15 seconds and more preferably within the range of 7 seconds to 12 seconds. When the initiation t3 of supplying the O₂ gas is excessively faster than the timing (namely, when t3 is earlier than 15 seconds before t4), the interior of the treatment container 1 is changed into an oxidation atmosphere before the plasma ignition, resulting in the metallic material being oxidized in a pre-heated state. When the initiation t3 of the supply of the O₂ gas is later than 5 seconds before the plasma ignition t4, time is taken for the O₂ gas to be introduced into the treatment container 1, degrading the oxidation quotient.

Also, the initiation t2 of the supply of H₂ gas may be at the same time as the initiation t3 of the supply of O₂ gas or earlier. When the initiation of the supply of H₂ gas is later than the initiation t3 of the supply of O₂ gas, there is a possibility in which the metallic material is oxidized by plasma of the O₂ gas until the H₂ gas becomes plasma.

The selective oxidation treatment is performed in a time duration from the time t4 at which plasma is ignited to the time t5 at which the supply of microwaves is stopped. After the supply of microwaves is stopped at t5, the supply of O₂ gas is stopped at t6, and then, the supply of H₂ gas is stopped at t7. In this manner, since the supply of H₂ gas is stopped after the supply of O₂ gas is stopped, the interior of the treatment container 1 is prevented from being changed into an oxidation atmosphere, thus restraining oxidation of the metallic material.

Also, subsequently, since the supply of Ar gas at the two lines is simultaneously stopped at t8, the selective oxidation treatment of one sheet of wafer W is terminated.

As described above, in the present disclosure, after the H₂ gas from the hydrogen gas supply source 19b is initiated to be supplied together with the first inert gas (Ar) from the first inert gas supply source 19a, the oxygen gas from the oxygen gas supply source 19d is then initiated to be supplied together with the second inert gas (Ar) from the second inert gas supply source 19c before igniting plasma. Since the supply timing of the O₂ gas comes immediately before the plasma ignition, the interior of the treatment container 1 can be maintained in the reduction atmosphere by the H₂ gas during the pre-heating period (t1 to t4), whereby the metallic material exposed in the surface of the wafer W can be restrained from being oxidized.

In order to supply the Ar gas, the H₂ gas and the O₂ gas at the timings as shown in FIG. 6, it is required to divide the supply path of the Ar gas serving as a carrier gas into two lines. By dividing the supply path of the Ar gas of a relatively large flow rate into two lines and using the Ar gas as a carrier of the H₂ gas and the O₂ gas of a small flow rate, a time taken for the H₂ gas and the O₂ gas to reach the interior of the treatment container 1 after being initiated to be supplied, respectively, can be easily controlled. Thus, the gases can be properly controlled and supplied at a stable flow rate, improving the reliability of the selective oxidation treatment. Also, since the Ar gas is used as a carrier, the time taken for the H₂ gas and O₂ gas to reach the interior of the treatment container 1 after being initiated to be supplied, respectively, is shortened, throughput of the selective oxidation treatment may also be improved.

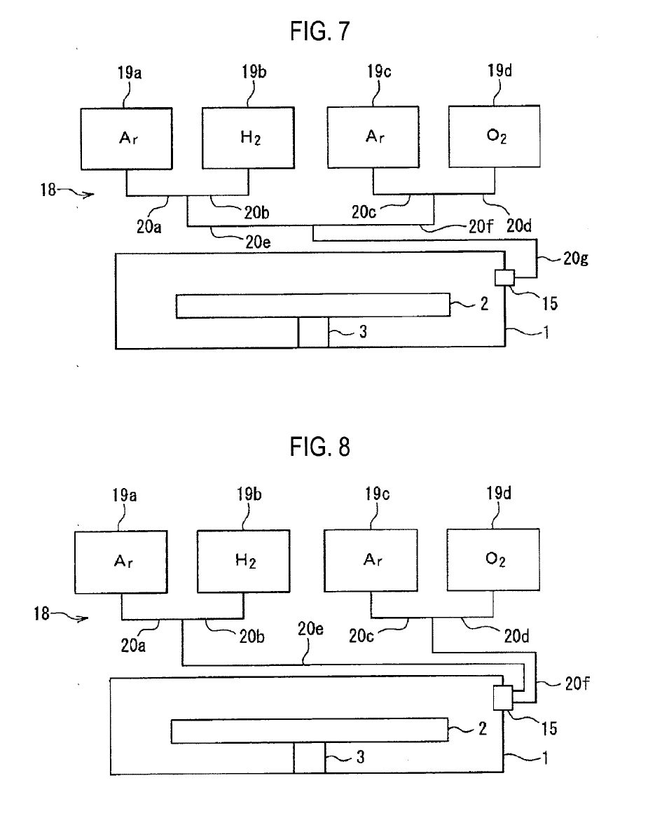

FIG. 7 shows an outline of the gas supply path in the plasma treatment apparatus 100. Also, illustration of the flow rate control device or valves is omitted. The first inert gas supply source 19a of the gas supply device 18 is connected to the gas line 20a, and the hydrogen gas supply source 19b is connected to the gas line 20b. The gas lines 20a and 20b join to be connected to the gas line 20e. Further, the second inert gas supply source 19c of the gas supply device 18 is connected to the gas line 20c, and the oxygen containing gas supply source 19d is connected to the gas line 20d. The gas lines 20c and 20d join to be connected to the gas line 20f. And the gas lines 20e and 20f join to become the gas line 20g so as to be connected to the gas introduction unit 15 of the treatment container 1. Half of the Ar gas is supplied through a first supply path including the gas lines 20a, 20e, and 20g from the first inert gas supply source 19a, so as to serve as a carrier of the hydrogen gas. Also, the other half of the Ar gas is supplied through a second supply path including the gas lines 20c, 20f, and 20g from the second inert gas supply source 19c, so as to serve as a carrier of the oxygen containing gas. In the configuration example of FIG. 7, the hydrogen gas and the oxygen containing gas are mixed immediately before they are introduced into the treatment container 1.

FIG. 8 shows another configuration example of the gas supply path in the plasma treatment apparatus 100. Also, in FIG. 8, the illustration of the flow rate control device or valves is omitted. The first inert gas supply source 19a of the gas supply device 18 is connected to the gas line 20a, and the hydrogen gas supply source 19b is connected to the gas line 20b. The gas lines 20a and 20b join to be connected to the gas line 20e. Further, the second inert gas supply source 19c of the gas supply device 18 is connected to the gas line 20c, and the oxygen containing gas supply source 19d is connected to the gas line 20d. The gas lines 20c and 20d join to be connected to the gas line 20f. And the gas lines 20e and 20f are connected to the gas introduction unit 15 of the treatment container 1. Half of the Ar gas is supplied through a first supply path including the gas lines 20a and 20e from the first inert gas supply source 19a, so as to serve as a carrier of the hydrogen gas. Also, the other half of the Ar gas is supplied through a second supply path including the gas lines 20c and 20f from the second inert gas supply source 19c, so as to serve as a carrier of the oxygen containing gas. In the configuration example of FIG. 8, the hydrogen gas and the oxygen containing gas are mixed within the treatment container 1.

[Operation]

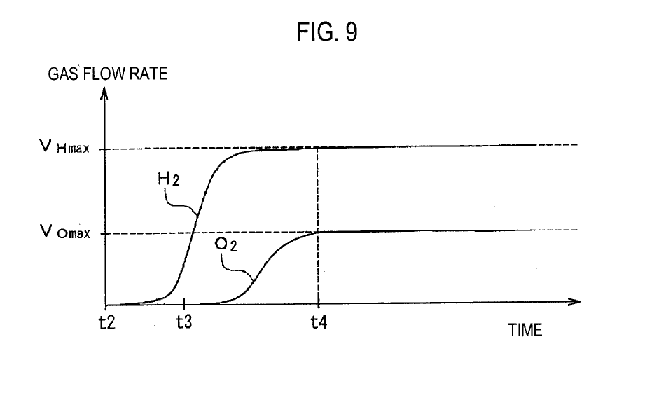

FIG. 9 shows a change in the flow rate of H₂ gas and O₂ gas within the treatment container 1. When the H₂ gas is initiated to be supplied at t2, the H₂ gas reaches the interior of the treatment container 1 through the gas lines 20b, 20e, and 20g, and soon, it has a maximum flow rate V_{Hmax} so as to be normally stabilized. When the O₂ gas is initiated to be supplied at t3, the O₂ gas reaches the interior of the treatment container 1 through the gas lines 20d, 20f, and 20g, and soon it has a maximum flow rate V_{Omax} so as to be normally stabilized. In order to restrain oxidization of the metal material, preferably, the interior of the treatment container 1 has a reduction atmosphere during the preheating period (t1 to t4), and inclination to the oxidation atmosphere is not preferred. To this end, it would be effective to adjust the initiation t2 of the supply of the H₂ gas such that it comes before the initiation t3 of the supply of the O₂ gas. Meanwhile, it is required to increase the oxidation quotient as much as possible while maintaining the balance between the oxidizing power and the reducing power within the treatment container 1 during (t4 to t5) of the selective oxidation treatment. To this end, preferably, both the flow rates of the H₂ and O₂ at the time t4 of the plasma ignition reach the maximum flow rates (V_{Hmax}, V_{Omax}) within the treatment container 1 and at the foregoing ratio of the preset volume flow rates. Thus, the supply timing of the O₂ gas comes ahead of the plasma ignition in consideration of the length of the pipes of the supply lines (gas lines 20d, 20f, and 20g) of the O₂ gas by a certain time. In this manner, in the selective oxidation treatment method according to the present disclosure, it is required to adjust the timing of the initiation t3 of supply of the O₂ gas such that it comes after the initiation t2 of the supply of the H₂ gas and before the plasma ignition t4. However, since the O₂ gas has a relatively small flow rate, a time taken for the O₂ gas to reach the maximum flow rate V_{Omax} from the initiation of its supply is easily changed depending on the length of the pipes of the supply path and the diameter of the pipes (the volume of the interior of the pipes), making it difficult to control the O₂ gas to reliably reach the maximum flow rate V_{Omax} at the time t4 of the plasma ignition only by the timing of the initiation t3 of the supply of the O₂ gas. Similarly, since the H₂ gas has a small flow rate, it is difficult to reliably control the H₂ gas to reliably reach the maximum flow rate V_{Hmax} at the time of the plasma ignition only by the timing of the initiation t2 of the supply of the H₂ gas. Thus, the time duration (i.e., from t2 to t4, from t3 to t4) in which the H₂ gas and the O₂ gas reach the interior of the treatment container 1 after being initiated to be supplied, respectively, becomes unstable, having the possibility of damaging the reliability of the selective oxidation treatment.

Therefore, in the present disclosure, the supply path of the Ar gas of a relatively large flow rate is divided into two lines and the Ar gas is used as a carrier of the H₂ gas and the O₂ gas of a small flow rate, to thus improve the controllability of the management of a time taken for the H₂ gas and the O₂ gas to reach the maximum flow rates V_{Hmax}, V_{Omax} within the treatment container 1 after being initiated to be supplied, respectively, thereby resolving instability of the gas supply. In this manner, the Ar gas, the H₂ gas, and the O₂ gas can all exist at the preset flow rate and flow rate ratio within the treatment container 1 at the plasma ignition t4. Also, since the Ar gas is divided into two lines and used as a carrier of the H₂ gas and the O₂ gas, the time duration (t2 to t4, t3 to t4) in which the H₂ gas and the O₂ gas reach the interior of the treatment container 1 after being initiated to be supplied, respectively, can be shortened, and since the H₂ gas and the O₂ gas reach the maximum flow rates V_{Hmax}, V_{Omax}, respectively, at the time t4 of the plasma ignition, the time duration (t4 to t5 in FIG. 6) of the selective oxidation treatment can also be shortened, thus improving the overall throughput. Thus, in the selective oxidation treatment method according to the present disclosure, oxidation of the metallic material and sputtering at the surface of the silicon can be prevented by the plasma of the mixture gas of the H₂ gas and the O₂ gas, and the selective oxidation treatment can be made at a high oxidation quotient.

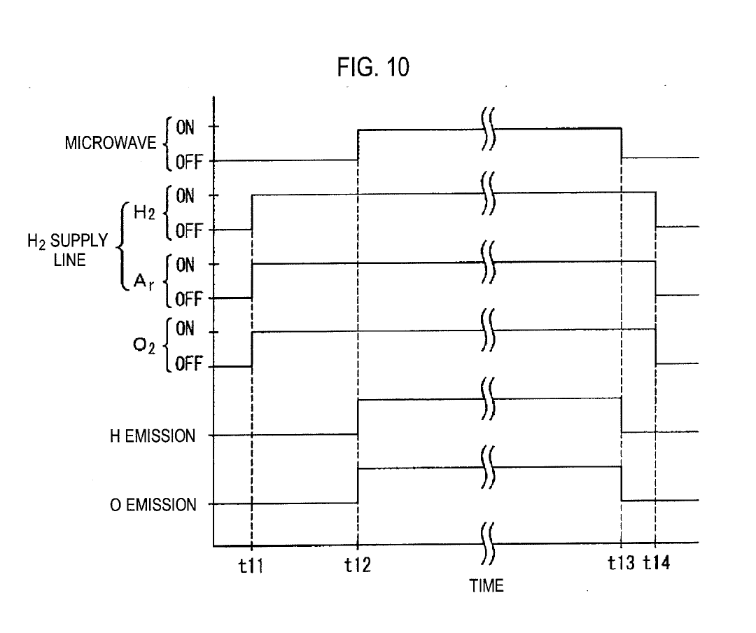

Next, the significance of seeking the timing of the O₂ introduction as mentioned above will be described with reference to FIGS. 6, and 10 to 13. FIG. 10 is a timing chart based on the conventional general gas supply sequence. In this example, the entire amount of Ar gas is supplied together with the H₂ gas. The supply of Ar gas, H₂ gas, and O₂ gas is initiated at t11, and power to the microwave is turned on at t12 to initiate supply of microwaves to thereby ignite plasma. At the time t12, since Ar gas, H₂ gas, and O₂ gas have been already introduced into the treatment container 1, emission of H radicals and O radicals are quickly observed. At t13, the power to the microwave is turned off to stop supply of microwaves, and at t14, the supply of Ar gas, H₂ gas, and O₂ gas is stopped. The interval from t12 to t13 is the period of the selective oxidation treatment. In the gas supply sequence of FIG. 10, the interior of the treatment container 1 is changed into oxidation atmosphere due to the O₂ gas during the pre-heating period from t11 at which the treatment gas is initiated to be supplied to t12 at which the plasma is ignited, oxidizing the metallic material.

Also, in the sequence of FIG. 10, it may be possible to set the timing of initiation of supply of the O₂ gas between the initiation t11 of supply of the H₂ gas and the plasma ignition t12, but since the O₂ gas of a small flow rate is supplied or the O₂ gas is solely supplied, the time duration from the initiation of supply of the O₂ gas to the time at which the O₂ gas reaches the interior of the treatment container 1 can be easily changed depending on the length of the pipes of the gas supply path, or the like, and cannot be easily controlled to lead to a failure of a stable selective oxidation treatment.

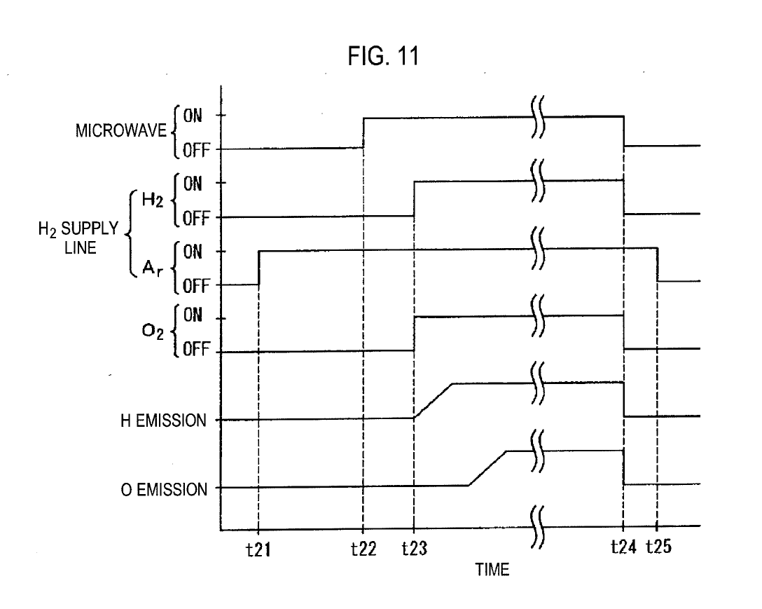

FIG. 11 is a first remedial measure to FIG. 10. In this example, the entire quantity of Ar gas is also supplied along with the H₂ gas. In the first remedial measure, the supply of the Ar gas is initiated at t21, power to the microwave is turned on at t22 to initiate supply of microwaves to thereby ignite plasma. Thereafter, the H₂ gas and the O₂ gas are simultaneously initiated to be supplied at t23. Namely, plasma is first ignited only by the Ar gas, and then, the H₂ gas and the O₂ gas are introduced into the treatment container 1. As shown in FIG. 11, since the H₂ gas is supplied by using the Ar gas of a large flow rate as a carrier, emission of H radicals is quickly generated after the initiation of the supply of the H₂ gas. However, since the O₂ is supplied at a small flow rate, it takes time for the O₂ gas to reach the interior of the treatment container 1 through the pipes so that emission of O radicals is generated later than that of H radicals. Thereafter, power to the microwave is turned off at t24 to stop the supply of microwaves, stop the supply of H₂ gas and O₂ gas, and also, at 25, the supply of the Ar gas is stopped. In the gas supply sequence of FIG. 11, time is taken from the initiation t22 (plasma ignition) of the supply of microwaves to the generation of oxygen plasma. Thus, at the initial stage following the plasma ignition, plasma of the Ar gas and H₂ gas having storing sputtering force is generated so that the silicon is not oxidized and the surface of the silicon is sputtered to roughen. Namely, in the gas supply sequence of FIG. 11, it takes time for the selective oxidation treatment, degrading the oxidation quotient and roughening the surface of the silicon.

Also, in the sequence of FIG. 11, it may be possible to set the timing of initiation of the supply of the O₂ gas between the initiation t21 of the supply of the Ar gas and the plasma ignition t22, but since the O₂ gas of a small flow rate is supplied or the O₂ gas is solely supplied, the time duration from the initiation of supply of the O₂ gas to the time at which the O₂ gas reaches the interior of the treatment container 1 can be easily changed depending on the length of the pipes of the gas supply path, or the like, and cannot be easily controlled to lead to a failure of a stable selective oxidation treatment.

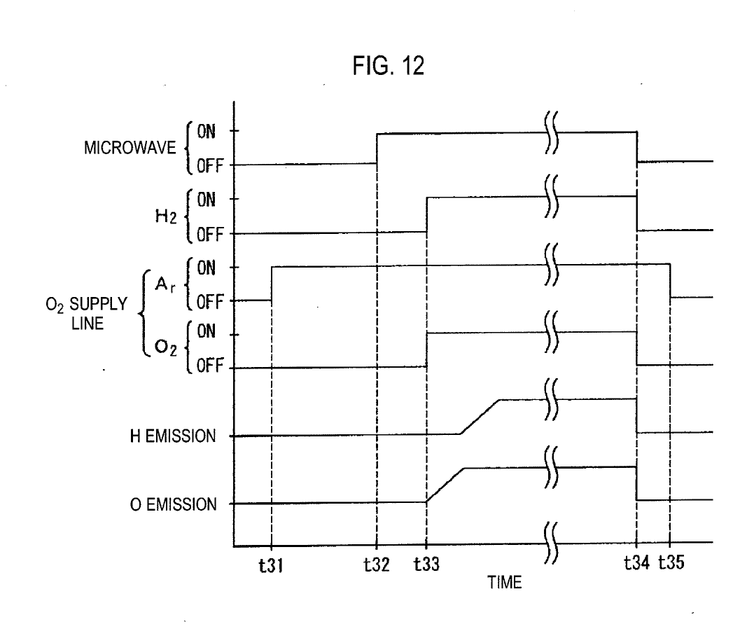

FIG. 12 is a gas supply sequence of second remedial measures in which the entire quantity of the Ar gas is supplied along with the O₂ gas, instead of the H₂ gas in FIG. 11. The timing of the initiation and stopping of the supply of each gas is the same as that of FIG. 11. First, at t31, the supply of Ar gas is initiated, and at t32, power to the microwave is turned on to initiate the supply of microwaves to thereby ignite plasma. Thereafter, at t33, the supply of H₂ gas and O₂ gas is simultaneously initiated. Thereafter, at t34, power to the microwave is turned off to stop supply of microwaves and simultaneously stop the supply of H₂ gas and the O₂ gas, and also at t35, the supply of the Ar gas is stopped. In FIG. 12, since the O₂ gas is supplied by using the Ar gas of a large flow rate as a carrier, the timing of the initiation of the supply of the H₂ gas and the O₂ gas is the same, but emission of O radicals is generated earlier than that of H radicals. However, since it takes time for the H₂ gas to reach the interior of the treatment container 1 through the pipes, the H₂ gas is not introduced into the treatment container 1 at the initial stage following the plasma ignition, oxidizing the metallic material by the plasma of the O₂ gas having strong oxidizing power. Also, since the O₂ gas is introduced following the plasma ignition, it takes time for the O₂ gas to reach a sufficient density within the treatment container 1, delaying the oxidation quotient of the selective oxidation treatment.

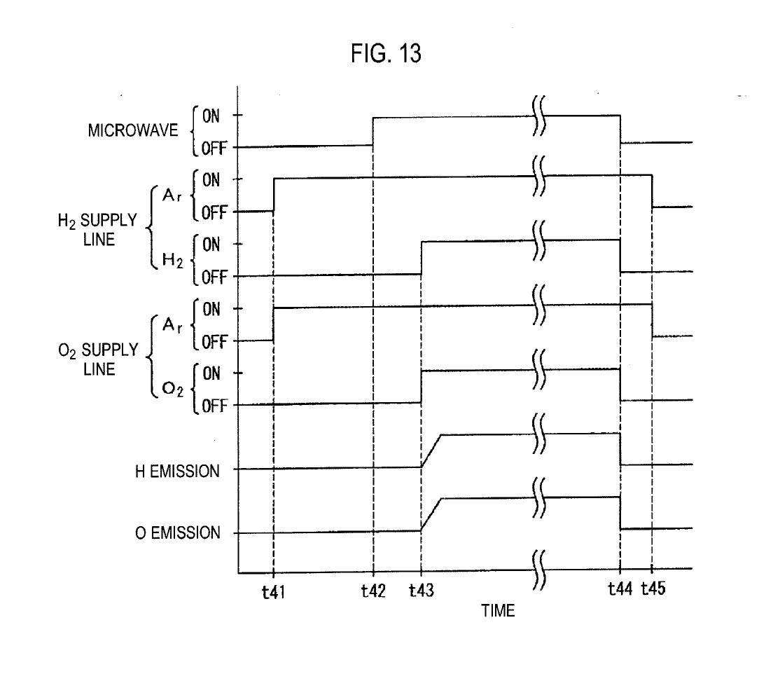

FIG. 13 shows a gas supply sequence of a third remedial measure in which the supply of the Ar gas is divided into two lines such that both lines have substantially the same quantity of the Ar gas, based on the gas supply sequences of FIGS. 11 and 12. The timing of the initiation and stopping of the supply of the respective gases is the same as that of FIGS. 11 and 12. First, at t41, the supply of the Ar gas of the two lines is initiated, respectively, and at t42, supply of microwaves is initiated to ignite plasma. Thereafter, at t43, the supply of the H₂ gas and the O₂ gas is simultaneously initiated. Next, at t44, the supply of microwaves, the H₂ gas, and the O₂ gas is stopped, and also at t45, the supply of the Ar gas is stopped. In the case of FIG. 13, since the Ar gas of a large flow rate is divided into two lines and used as a carrier gas, and the H₂ gas and the O₂ gas are supplied, emission of H radicals and that of O radicals are almost simultaneously generated after the supply of the H₂ gas and the O₂ gas is initiated. Accordingly, the oxidation of the metallic material can be restrained, but it takes time for the H₂ gas and the O₂ gas to reach the interior of the treatment container 1 through the pipes at the initial stage following the plasma ignition. Thus, since the H₂ gas and the O₂ gas have not reached a sufficient density within the treatment container 1, it takes time for the selective oxidation treatment, making it difficult to improve the oxidation quotient.

Meanwhile, in the gas supply sequence (FIG. 6) of the present disclosure, since the timing t3 for supplying the O₂ gas is in standby immediately before the timing t4 of plasma ignition, oxidation of the metallic material exposed in the surface of the wafer W can be restrained during the pre-heating period (t1 to t4). Also, the timing for supplying the O₂ gas is adjusted to be earlier by a certain time than the plasma ignition and the supply of the H₂ gas is previously initiated, in consideration of the length of the pipes of the supply path of the O₂ gas. Accordingly, the Ar gas, the H₂ gas, and the O₂ gas all exist within the treatment container 1 when the plasma is ignited, thus preventing oxidization of the metallic material or sputtering on the surface of the silicon and obtaining high oxidation quotient.

Now, experimental data based on the present disclosure will be described. In each test, a wafer having a TiN film and wafer having a W (tungsten) film, each as a metallic material, was used.

### Experimental Example 1

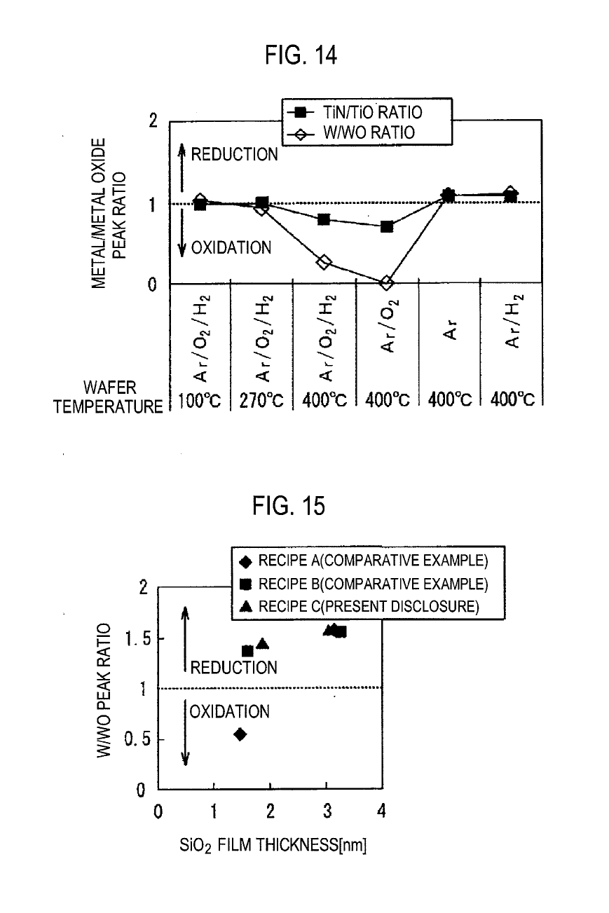

Each wafer was transferred into the treatment container 1 of the plasma treatment apparatus 100 and loaded on the loading table 2 whose temperature was adjusted to be within the range of 100 degrees C. to 400 degrees C. The interior of the treatment container 1 was adjusted to have a pressure of 667 Pa (5 Torr), Ar/O₂/H₂, Ar/O₂, Ar or Ar/H₂ was introduced as a treatment gas, each wafer was exposed to each gas atmosphere for a certain period of time, and then, the surface of each wafer was analyzed through X-ray photoelectron spectroscopy (XPS). The results are shown in FIG. 14. In FIG. 14, a vertical axis is the ratio between a peak area of a metal and that of a metal oxide, in which when the ratio is 1, it indicates a non-treated state (comparison), when the ratio is smaller than 1, it indicates that the metal was oxidized, and when the ratio exceeds 1, it indicates that the metal was reduced.

In FIG. 14, it is noted that, when the metal/metal oxide is exposed to the Ar/O₂/H₂ atmosphere or the Ar/O₂ atmosphere at a wafer temperature of 400 degrees C., the ratio of the peak area of the metal/metal oxide was smaller than 1, which means that the metallic material was oxidized. These conditions are substantially equivalent to the conditions of the pre-heating period (from t11 to t14 in FIG. 10) in the gas supply sequence of the related art selective oxidation treatment. Thus, it is obvious that, in the gas supply sequence of the related art selective oxidation treatment, the metal material is oxidized due to the introduction of the oxygen gas during the pre-heating period.

### Experimental Example 2

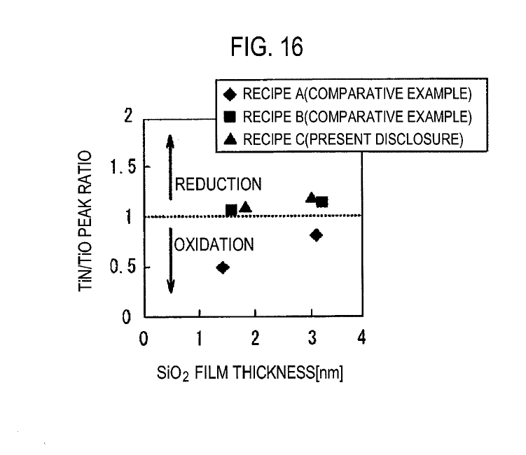

A selective oxidation treatment was performed under the following conditions based on the gas supply sequence as shown in the timing chart of FIG. 6 as an example of the present disclosure and the gas supply sequence as shown in the timing charts of FIGS. 12 and 13 as comparative examples, and XPS analysis was performed in the same manner as that of Experimental Example 1 to inspect an oxidation state of the metallic material. Also, the gas supply sequence of FIG. 12 was referred to as ‘sequence A’, that of FIG. 13 was referred to as ‘sequence B’, and that of FIG. 6 was referred to as ‘sequence C’. FIG. 15 shows the results of the W film and FIG. 16 shows the results of the TiN film. Also, the horizontal axes in FIGS. 15 and 16 indicate a film thickness of an SiO₂ film formed through the selective oxidation treatment.

[Common Conditions of Plasma Oxidation]
A plasma treatment apparatus having the same configuration as that of FIG. 1 was used.
Ar gas flow rate: 480 mL/min(sccm) (240 mL/min for each of two lines)
O₂ gas flow rate: 4 mL/min(sccm)
H₂ gas flow rate: 16 mL/min(sccm)
Treatment pressure: 667 Pa (5 Torr)
Temperature of loading table: 400 degrees C.
Microwave power: 4000 W
Microwave power density: 2.05 W/cm² (per 1 cm² of the area of transmission plate)

In FIG. 15, it is noted that, in the selective oxidation of the W film and in the sequence A of FIG. 12, H emission was delayed compared with 0 emission so that tungsten was already oxidized immediately after the plasma ignition (SiO₂ film 1.5 nm), and thereafter, tungsten was reduced in the selective oxidation treatment up to SiO₂ film 3 nm. Accordingly, it is noted that, O emission and H emission are simultaneously made at the sequence B of FIG. 13 and the sequence C of FIG. 6 so that tungsten is constantly in a reduced state from immediately after the plasma ignition up to SiO₂ film 3 nm.

Similarly, also in the selective oxidation of the TiN film, in the sequence A of FIG. 12, since H emission was delayed compared with 0 emission, TiN was already oxidized immediately after the plasma ignition (SiO₂ film 1.5 nm), and thereafter, TiN started to recover in the direction of reduction in the selective oxidation treatment up to SiO₂ film 3 nm, but it is not recovered yet till the initial state but is in an oxidized state. Accordingly, it is noted that, O emission and H emission are simultaneously made at the sequence B of FIG. 13 and the sequence C of FIG. 6 so that TiN is constantly in the reduced state from immediately after the plasma ignition to the SiO₂ film 3 nm.

Thereafter, an oxidation quotient was measured until the SiO₂ film of 3 nm was formed in each sequence. Table 1 below shows the results. In the sequence A (FIG. 12) and sequence B (FIG. 13) in which the supply of O₂ gas was initiated after the plasma ignition, 242 seconds were required in the sequence A and 140 seconds were required in the sequence B to form the SiO₂ film with a film thickness of 3 nm. Meanwhile, in the sequence C (FIG. 6) in which the supply of the O₂ gas was initiated 10 seconds before the plasma was ignited, merely 59 seconds were taken to form the SiO₂ film with a film thickness of 3 nm, obtaining high oxidation quotient.

TABLE 1

| | Sequence A | Sequence B | Sequence C |
|---|---|---|---|
| | (FIG. 12) | (FIG. 13) | (FIG. 6) |
| Timing of | After five seconds | After five seconds | 10 seconds |
| initiation | from plasma | from plasma | before plasma |
| of supply | ignition | ignition | ignition |
| of O₂ gas | | | |
| Emission timing | H emission after | O and H | O and H |
| | O emission (there | simultaneous | simultaneous |
| | is a time differ- | emission (there | emission |
| | ence from plasma | is a time differ- | (immediately |
| | ignition) | ence from plasma | after plasma |
| | | ignition) | ignition) |
| Oxidation of | Oxidized | Not oxidized | Not oxidized |
| metal material | | | |
| Oxidation | 242 seconds | 140 seconds | 59 econds |
| quotient (time | | | |
| taken for form- | | | |
| ing film of | | | |
| 3 nm) | | | |

As described above, according to the selective oxidation method of the present disclosure, the inert gas as a carrier gas is divided into two lines, the hydrogen gas is initiated to be supplied together with the inert gas, and then, the oxygen containing gas is initiated to be supplied together with the inert gas before plasma is ignited, whereby the metal material exposed in the surface of the wafer W can be restrained from being oxidized to its maximum level and the surface of the silicon can be selectively oxidized at a high oxidation quotient. Also, the surface roughness of the silicon due to sputtering can be prevented.

In the selective oxidation method of the present disclosure, as shown in FIG. 6, emission of the H radicals and O radicals is generated at the timing t4 at which a microwave is introduced. Accordingly, based on the sequence of FIG. 6, the supplies of the Ar gas, H₂ gas, the O₂ gas are sequentially initiated in this order, and also, since the timing of the emission of the H radicals and O radicals after the microwave is introduced (plasma is ignited) is measured by the monochromator 43, it is monitored whether or not the timing of the introduction of the H₂ gas and the O₂ gas into the treatment container 1 is suitable, to thus improve the reliability of the selective oxidation treatment. When the emission of the H radicals and that of the O radicals are simultaneously generated immediately after the introduction of the microwave (plasma ignition), it means that the selective oxidation treatment is accurately performed based on the gas supply sequence of FIG. 6. Meanwhile, if emission of the H radicals becomes fast because the gas supply sequence of FIG. 6 is not accurately executed for some reason, it is possible that the silicon surface will be rough due to sputtering and if emission of O radicals becomes fast, it is possible that the metallic material will be oxidized.

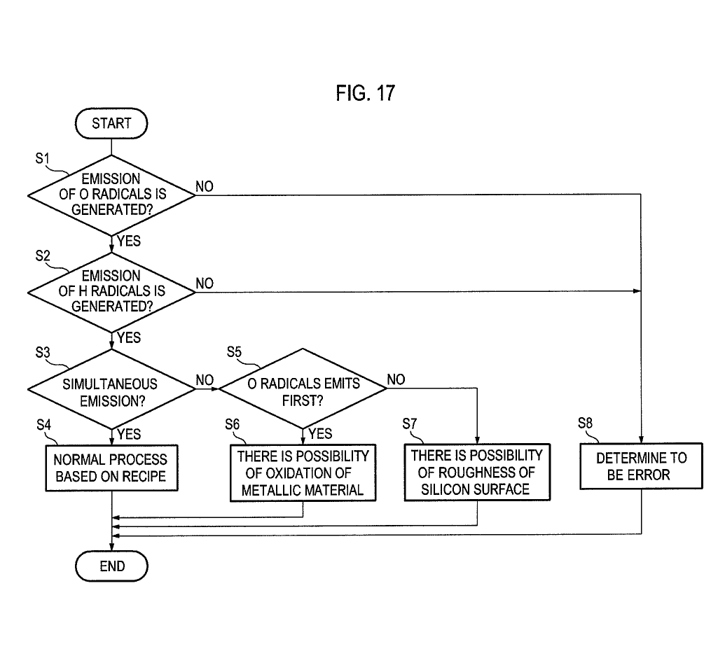

FIG. 17 is a flowchart illustrating an example of the process of determining reliability of the selective oxidation treatment by monitoring the timing of the emission of H radicals and O radicals by using the monochromator 43. Based on the timing chart of FIG. 6, after microwaves are introduced (plasma is ignited) at t4, it is first determined in step S1 whether or not emission of O radicals is measured. When the O radicals are emitted (YES), it is then determined in step S2 whether or not emission of H radicals is measured. When H radicals are emitted (YES) in step S2, it is then determined in step S3 whether or not H radicals and O radicals are simultaneously emitted. Also, when emission of O radicals is not observed (NO) in step S1 and when emission of H radicals is not observed (NO) in step S2, there is a possibility in which the plasma process itself is not normally performed. If so, it is impossible to determine the process. In this case, it is determined to be an error in step S8, and hence the process stops and an error message is delayed.

When H radicals and O radicals simultaneously emit (YES) in step S3, it may be determined that the selective oxidation treatment is normally performed based on the gas supply sequence of FIG. 6 in step S4. Meanwhile, when H radicals and O radicals do not simultaneously emit (NO) in step S3, it is determined in step S5 whether or not O radicals are emitted first. When it is determined that O radicals are emitted first (YES) in step S5, there is a possibility in which the metallic material was oxidized due to oxygen plasma in a state without hydrogen at the initial stage of the selective oxidation treatment so that it may be determined in step S6 that there is a possibility of oxidation of the metallic material. Meanwhile, when O radicals are not emitted first (NO) in step S5, since it means that H radicals are emitted first, there is a possibility in which the silicon surface was sputtered by plasma of Ar/H₂ gas in a state without oxygen in the initial stage of the selective oxidation treatment, so it may be determined that there is a possibility the silicon surface is rough in step S7.

In this manner, by monitoring the timing of the emission of H radicals and O radicals by using the monochromator 43, whether or not the gas supply sequence of FIG. 6 is normally executed (in other words, whether or not the balance between oxidizing power and reducing power in the treatment container 1 is maintained to be in a desired state so that the selective oxidation treatment is properly performed) can be determined

As described above, the embodiments of the present disclosure have been described, but the present disclosure is not limited to the foregoing embodiments and may be modified. For example, in the foregoing embodiment, the RLSA type microwave plasma treatment apparatus is used for the selective oxidation treatment, but any other type plasma treatment apparatus such as, for example, an ICP plasma type, an ECR plasma type, a surface reflective plasma type, a magnetron plasma type, or the like may be used. The present disclosure can be applicable to any plasma treatment apparatus for generating plasma by electromagnetic waves including microwave or high frequency.

Also, the selective oxidation treatment method according to the present disclosure is not limited to the lamination body having the MONOS structure in the fabrication process of the flash memory device, but can be widely applicable to a case in which a plasma selective oxidation treatment is performed on an object to be treated in which silicon and a metallic material are exposed in the surface.

According to the present disclosure, it is possible to selectively oxidize a silicon surface with a high oxidation quotient while minimizing the oxidation of a metallic material exposed on the surface of an object to be treated. It is also possible to prevent the silicon surface from being roughened.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A selective oxidation treatment method in which plasma of a hydrogen gas and an oxygen containing gas is allowed to act on an object to be treated, in which silicon and a metallic material are exposed in the surface, within a treatment container of a plasma treatment apparatus so as to selectively oxidize the silicon by the plasma, the method comprising:
after the supply of the hydrogen gas from a hydrogen gas supply source is initiated by using a first inert gas, which passes through a first supply path, as a carrier gas, initiating the supply of the oxygen containing gas from an oxygen containing gas supply source by using a second inert gas, which passes through a second supply path different from the first supply path, as a carrier gas before the plasma is ignited; and
igniting the plasma of a treatment gas including the oxygen containing gas and the hydrogen gas within the treatment container.

2. The method of claim 1, wherein, at the timing of igniting the plasma, the hydrogen gas and the oxygen containing gas have been introduced at a certain ratio of the volume flow rates into the treatment container.

3. The method of claim 2, wherein the ratio (hydrogen gas flow rate: oxygen containing gas flow rate) of the volume flow rates between the hydrogen gas and the oxygen containing gas ranges from 1:1 to 10:1.

4. The method of claim 1, wherein the timing at which the supply of the oxygen containing gas is initiated ranges between 5 seconds and 15 seconds before the time at which plasma is ignited.

5. The method of claim 1, wherein the object to be treated is pre-heated under a reduction atmosphere within the treatment container until the oxygen containing gas is introduced into the treatment container.

6. The method of claim 1, wherein, in the igniting and the selectively oxidizing, emission of oxygen atoms and emission of hydrogen atoms in the plasma are measured to monitor whether or not the timing at which the hydrogen gas and the oxygen containing gas are introduced into the treatment container is suitable.

7. The method of claim 1, wherein the plasma treatment apparatus generates plasma by introducing microwaves into the treatment container by a planar antenna having multiple holes.

8. A selective oxidation treatment apparatus, the apparatus comprising:
a treatment container configured to accommodate an object to be treated;
a loading table configured to load the object to be treated within the treatment container;
a gas supply device configured to supply a treatment gas to the interior of the treatment container;
an exhaust device configured to decompress and exhaust the interior of the treatment container;
a plasma generation unit configured to introduce electromagnetic waves into the treatment container to generate plasma of the treatment gas; and
a controller configured to provide control to allow the plasma generated within the treatment container to act on the object to be treated, in which silicon and a metallic material are exposed in the surface, in order to selectively oxidize the silicon,
wherein the gas supply device includes a first inert gas supply source, a second inert gas supply source, a hydrogen gas supply source, and an oxygen containing gas supply source, and has inert gas supply paths of two lines including a first supply path for supplying a first inert gas from the first inert gas supply source to the treatment container and a second supply path for supplying a second inert gas from the second inert gas supply source to the treatment container.

9. The apparatus of claim 8, wherein the controller is configured to provide control to perform a selective oxidation treatment comprising:
after the supply of the hydrogen gas from a hydrogen gas supply source is initiated by using a first inert gas, which passes through a first supply path, as a carrier gas, initiating the supply of the oxygen containing gas from an oxygen containing gas supply source by using a second inert gas, which passes through a second supply path, as a carrier gas before the plasma is ignited;
igniting the plasma of a treatment gas including the oxygen containing gas and the hydrogen gas within the treatment container; and
selectively oxidizing the silicon by the plasma.

10. A computer-readable memory medium having a control program operating on a computer stored thereon,
wherein the control program, when executed, causes the computer to provide control to perform a selective oxidation treatment method in which plasma of a hydrogen gas and an oxygen containing gas is allowed to act on an object to be treated, in which silicon and a metallic material are exposed in the surface, within a treatment container of a plasma treatment apparatus so as to selectively oxidize the silicon,
the selective oxidation treatment method comprising:
after the supply of the hydrogen gas from a hydrogen gas supply source is initiated by using a first inert gas, which passes through a first supply path, as a carrier gas, initiating the supply of the oxygen containing gas from an oxygen containing gas supply source by using a second inert gas, which passes through a second supply path different from the first supply path, as a carrier gas before the plasma is ignited; and
igniting the plasma of a treatment gas including the oxygen containing gas and the hydrogen gas within the treatment container.
